(19) United States
(12) Patent Application Publication
(10) Pub. No.: US 2006/0110688 A1
(43) Pub. Date: May 25, 2006

(54) Etching process compatible with DUV lithography

(76) Inventors: Chung-Ju Lee, Hsinchu Hsien (TW); Chih-Ning Wu, Hsinchu (TW); Kuan-Yang Liao, Taipei City (TW)

Correspondence Address: J C PATENTS, INC., 4 VENTURE, SUITE 250, IRVINE, CA, 92618, US

(21) Appl. No.: 10/993,593

(22) Filed: Nov. 19, 2004

(51) Int. Cl. G03F 7/36

(52) U.S. Cl. 430/323

(57) ABSTRACT

An etching process compatible with DUV lithography is described. A mask layer is previously formed over a material layer to be etched through a DUV lithography process of 193 nm or 157 nm. Then, plasma etching is performed to pattern the material layer using the mask layer as an etching mask, wherein the etching gas causes a protective layer to form on the surface of the mask layer. The etching gas of the plasma etching includes at least a halogen-containing gas and Xe, wherein the halogen can be F, Cl, Br or a combination thereof.

### BACKGROUND OF THE INVENTION

1. Field of the Invention

The present invention relates to an etching process. More particularly, the present invention relates to a plasma etching process compatible with deep-ultraviolet (DUV) lithography.

2. Description of Related Art

As the IC industry continuously grows, it is always desired to scale down IC devices and increase the integration degree of IC devices. In IC fabrication, etching steps are important from front-end processes to back-end processes, and are frequently key steps in combination with lithography steps. The etching techniques can be divided into two categories including wet etching and dry etching, wherein the dry etching technique is particularly required for effecting anisotropic etching.

Among dry etching techniques, plasma etching techniques are most important. In a plasma etching process, plasma is generated to convert molecules of the reaction gas into ions that will bombard the film to be etched. The reaction of the film with the ions produces volatile products that will be drawn out by the vacuum system, thus effecting the etching process.

In an etching process subsequent to a lithography process that forms a patterned photoresist layer on the film to be patterned, the film is etched using the photoresist layer as a mask so that the photoresist patterns are transferred to the film. During the etching process, the photoresist layer is also recessed due to bombardment of the ions in the plasma.

However, when the lithography technology advances to the DUV generation, especially the generation of 193 nm or 157 nm, cavities or striations further form on the surface of the photoresist layer specifically used in 193 nm or 157 nm lithography during the etching process. Therefore, the top surface and the profile of the patterned photoresist layer are roughened, while the roughened profile of the photoresist layer will be transferred to the underlying film lowering the pattern quality thereof.

### SUMMARY OF THE INVENTION

Accordingly, one object of this invention is to provide an etching process compatible with DUV lithography that can prevent the profile of the mask layer from being roughened due to bombardment of the ions in the plasma.

An etching process compatible with DUV lithography of this invention is described as follows. A material layer to be patterned is provided with a mask layer formed thereon, wherein the mask layer is previously formed through a DUV lithography process of 193 nm or 157 nm. Then, plasma etching is performed to pattern the material layer using the mask layer as a mask. The etching gas used in the plasma etching step includes at least a halogen-containing gas and xenon (Xe), wherein the halogen can be fluorine (F), chlorine (Cl), bromine (Br) or a combination thereof.

The addition of xenon in the plasma etching step can prevent the mask layer from being bombarded by the reactive ions, so that the profile of the same is not roughened.

Another etching process compatible with DUV lithography of this invention is also described. A material layer to be patterned is provided with a mask layer formed thereon, wherein the mask layer is previously formed through a DUV lithography process of 193 nm or 157 nm. Then, plasma etching is performed to pattern the material layer using the mask layer as a mask, wherein the etching gas causes a protective layer to form on the mask layer. The etching gas includes at least a halogen-containing gas and Xe, wherein the halogen can be F, Cl, Br or a combination thereof.

By using a halogen-containing gas and Xe in the plasma etching, a protective layer can be formed on the mask layer when the material layer is being etched. Therefore, the mask layer is protected from bombardment of the ions, so that the patterns on the mask layer can be completely transferred to the material layer.

It is to be understood that both the foregoing general description and the following detailed description are exemplary, and are intended to provide further explanation of the invention as claimed.

### BRIEF DESCRIPTION OF THE DRAWINGS

FIGS. 1A-1C illustrate an etching process compatible with DUV lithography according to an embodiment of this invention in a cross-sectional view.

FIG. 2 illustrate an etching process compatible with DUV lithography according to another embodiment of this invention in a cross-sectional view.

### DESCRIPTION OF THE PREFERRED EMBODIMENTS

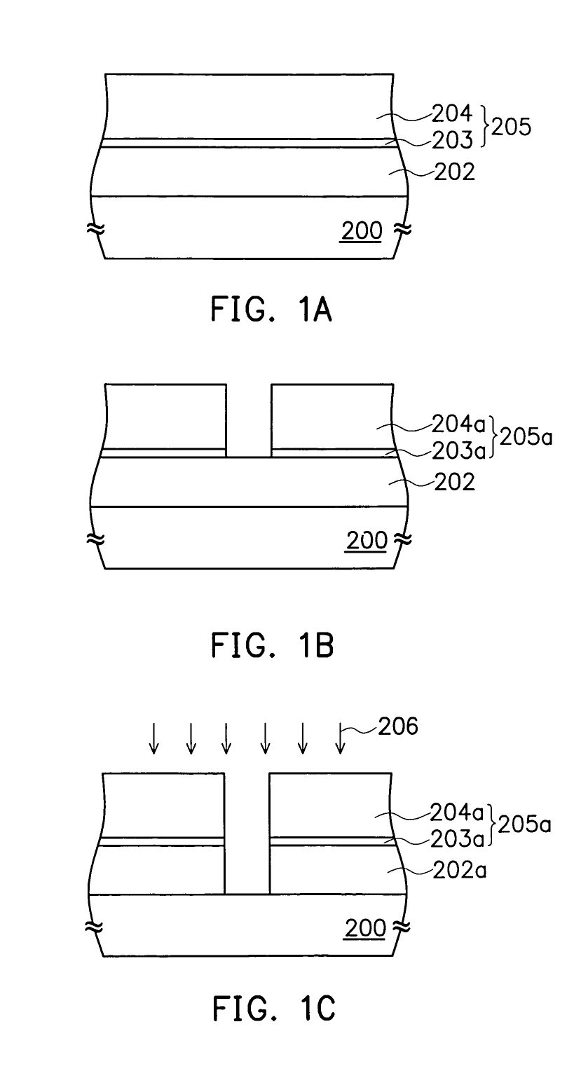

Referring to FIG. 1A, a substrate 200 formed with a material layer 202 and a blanket mask layer 205 thereon is provided. The material layer 202 is, for example, a dielectric layer or a conductive layer, wherein the dielectric layer may include silicon nitride, silicon oxide, silicon oxynitride or a low-k material, and the conductive layer may include polysilicon or metal.

Referring to FIG. 1C, a DUV lithography process is performed, using a DUV light source of 193 nm or 157 nm, for example, to pattern the blanket mask layer 205 into a patterned mask layer 205a. The patterned mask layer 205a is used as an etching mask in the subsequent etching process compatible with the DUV lithography process.

In a preferred embodiment, the blanket mask layer 205 may be a blanket photoresist layer 204, and the method for patterning the photoresist layer 204 may include a lithography process, which forms a patterned photoresist layer 204a. The photoresist layer 204 can be formed from a photosensitive material that contains a resin, a photo-sensitive agent and a solvent and is specifically used in DUV lithography of 193 nm or 157 nm. The photoresist layer 204 may be formed using a spin coating method, wherein a fluid photosensitive material is coated on the material layer 202 with spin-on operation, and then soft-bake is conducted to remove the solvent from the photosensitive material so that the fluid photosensitive material is converted to a solid photoresist layer 204.

In another embodiment, the mask layer 205 may further include a bottom anti-reflection coating (BARC) 203 under the photoresist layer 204. The BARC 203 can be formed on the material layer 202 with chemical vapor deposition (CVD) or spin coating, and the material of the same can be organic or inorganic. In this case, the photoresist layer 204 may be patterned using a lithography method, and then the BARC 203 may be patterned using an etching method to formed a patterned mask layer 205a including a patterned BARC 203a and a patterned photoresist layer 204a.

Referring to FIG. 1C, plasma etching 206 is performed to etching the material layer 202 into a patterned material layer 202a using the mask layer 205a as a mask. The etching gas used in the plasma etching 206 includes at least a halogen-containing gas and xenon (Xe), wherein the halogen can be F, Cl, Br or a combination thereof. When the halogen is fluorine (F), the halogen-containing gas may be CF₄, C₄F₈, CH₃F, CHF₃, CF₂H₂ or a combination thereof. When the halogen includes chlorine (Cl), the halogen-containing gas may be Cl₂, BCl₃, CFCl₃, CF₂Cl₂, CF₃Cl or a combination thereof. When the halogen includes bromine (Br), the halogen-containing gas may be HBr, CF₃Br, CF₂ClBr or a combination thereof. The etching gas may further include other gas, such as, O₂, N₂ or a combination thereof to meet specific requirements.

Moreover, in the etching gas used in the plasma etching step, the ratio of the halogen-containing gas to xenon is preferably from 0.02 to 1.0, more preferably from 0.1 to 1.0.

In this embodiment, the addition of xenon in the plasma etching can prevent the mask layer from being bombarded by the ions, so that the profile of the same is not roughened. This is because xenon is ionized more easily as compared with argon or helium, while the xenon ions are distributed near the mask layer and can capture the halogen ions generated from the halogen-containing gas to protect the surface of the mask layer 205a from being bombarded by the ions.

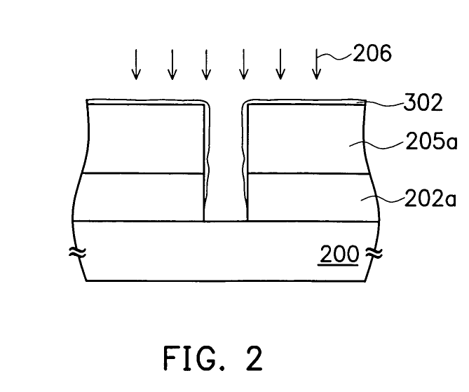

In another embodiment, when the plasma etching 206 is being performed using the mask layer 205a as a mask and a mixture of halogen-containing gas and xenon as an etching gas, xenon ions further form chemical bonds with the halogen ions to form a protective layer 302 on the mask layer 205a, as shown in FIG. 2. The protective layer 302 may include xenon halide (XeXₚ), and covers at least the surface of the mask layer 205 to prevent it from being bombarded by the ions to have cavities or striation thereon.

The halogen in the halogen-containing gas in the above-mentioned etching gas can be F, Cl, Br or a combination thereof. When the halogen is F, the halogen-containing gas may be CF₄, C₄F₈, CH₃F, CHF₃, CF₂H₂ or a combination thereof, and the protective layer 302 may include a xenon fluoride (XeFₚ₁) compound, such as, XeF₂ or XeF₄. When the halogen includes Cl, the halogen-containing gas may be Cl₂, BCl₃, CFCl₃, CF₂Cl₂, CF₃Cl or a combination thereof, and the protective layer 302 may include a xenon chloride (XeClₚ₂) compound, such as, XeCl₄ or XeCl₂. When the halogen includes Br, the halogen-containing gas may be HBr, CF₃Br, CF₂ClBr or a combination thereof, and the protective layer 302 may include a xenon bromide (XeBrₚ₃) compound, such as, XeBr or XeBr₂. In addition, according to the requirement in etching rate, the etching gas can be further added with other gas, such as, O₂, N₂ or a combination thereof.

In the above embodiment, the protective layer 302 can prevent the surface of the patterned mask layer 205a from being bombarded by the ions to rougher.

In summary, the addition of xenon in the plasma etching can prevent the mask layer from being bombarded by the ions to roughen. Moreover, the etching gas can further cause a protective layer 302 to form on the mask layer 205a. The protective layer 302 can prevent the surface of the mask layer 205a from being bombarded by the ions, so that the patterns of the mask layer can be completely transferred to the material layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An etching process compatible with DUV lithography, comprising:
providing a material layer formed with a mask layer thereon, wherein the mask layer is previously formed through a DUV lithography process of 193 nm or 157 nm; and
performing plasma etching to pattern the material layer using the mask layer as a mask, wherein an etching gas of the plasma etching comprises at least a halogen-containing gas and Xe, wherein the halogen is fluorine (F), chlorine (Cl), bromine (Br) or a combination thereof.

2. The etching process of claim 1, wherein the halogen is F and the halogen-containing gas is selected from the group consisting of CF₄, C₄F₈, CH₃F, CHF₃, CF₂H₂ and combinations thereof.

3. The etching process of claim 1, wherein the halogen includes Cl and the halogen-containing gas is selected from the group consisting of Cl₂, BCl₃, CFCl₃, CF₂Cl₂, CF₃Cl and combinations thereof.

4. The etching process of claim 1, wherein the halogen includes Br and the halogen-containing gas is selected from the group consisting of HBr, CF₃Br, CF₂ClBr and combinations thereof.

5. The etching process of claim 1, wherein in the etching gas, a ratio of the halogen-containing gas to xenon is from 0.02 to 1.0.

6. The etching process of claim 5, wherein in the etching gas, a ratio of the halogen-containing gas to xenon is from 0.1 to 1.0.

7. The etching process of claim 1, wherein the etching gas further comprises a gas selected from the group consisting of O₂, N₂ and combinations thereof.

8. The etching process of claim 1, wherein the material layer comprises a dielectric layer or a conductive layer.

9. The etching process of claim 1, wherein the mask layer comprises a photoresist layer.

10. The etching process of claim 1, wherein the mask layer comprises a bottom anti-reflection coating (BARC) and a photoresist layer thereon.

11. An etching process compatible with DUV lithography, comprising:
providing a material layer formed with a mask layer thereon, wherein the mask layer is previously formed through a DUV lithography process of 193 nm or 157 nm; and
performing plasma etching to pattern the material layer using the mask layer as a mask, wherein an etching gas of the plasma etching comprises at least a halogen-containing gas and Xe, and the etching gas causes a protective layer to form on the mask layer, wherein the halogen is fluorine (F), chlorine (Cl), bromine (Br) or a combination thereof.

12. The etching process of claim 11, wherein the halogen is F and the halogen-containing gas is selected from the group consisting of CF₄, C₄F₈, CH₃F, CHF₃, CF₂H₂ and combinations thereof.

13. The etching process of claim 11, wherein the halogen includes Cl and the halogen-containing gas is selected from the group consisting of Cl₂, BCl₃, CFCl₃, CF₂Cl₂, CF₃Cl and combinations thereof.

14. The etching process of claim 11, wherein the halogen includes Br and the halogen-containing gas is selected from the group consisting of HBr, CF₃Br, CF₂ClBr and combinations thereof.

15. The etching process of claim 11, wherein in the etching gas, a ratio of the halogen-containing gas to xenon is from 0.02 to 1.0.

16. The etching process of claim 11, wherein the protective layer comprises a xenon halide (XeXₚ) layer.

17. The etching process of claim 11, wherein the etching gas further comprises a gas selected from the group consisting of O₂, N₂ and combinations thereof.

18. The etching process of claim 11, wherein the material layer comprises a dielectric layer or a conductive layer.

19. The etching process of claim 11, wherein the mask layer comprises a photoresist layer.

20. The etching process of claim 11, wherein the mask layer comprises a bottom anti-reflection coating (BARC) and a photoresist layer thereon.
